(19) United States
(12) Patent Application Publication
(10) Pub. No.: US 2015/0295149 A1
(43) Pub. Date: Oct. 15, 2015

(54) LED PACKAGE AND METHOD FOR MANUFACTURING SAME

(71) Applicants: Hak Hwan Kim, Suwon-si (KR); Hyung Kun Kim, Suwon-si (KR); Sung Kyong Oh, Suwon-si (KR)

(72) Inventors: Hak Hwan Kim, Suwon-si (KR); Hyung Kun Kim, Suwon-si (KR); Sung Kyong Oh, Suwon-si (KR)

(73) Assignee: SAMSUNG ELECTRONICS CO., LTD., Suwon-si, Gyunggi-do (KR)

(21) Appl. No.: 14/235,045

(22) PCT Filed: Jul. 25, 2011
(86) PCT No.: PCT/KR11/05459

§ 371 Date: Jan. 24, 2014

(51) Int. Cl. H01L 33/62; H01L 33/56; H01L 33/64; H01L 33/58

(52) U.S. Cl. CPC H01L 33/62; H01L 33/58; H01L 33/56; H01L 33/642; H01L 2933/005; H01L 2933/0033; H01L 2933/0066; H01L 2933/0075

(57) ABSTRACT

There are provided a light emitting diode (LED) package including a heat slug to have excellent heat dissipation efficiency and a manufacturing method thereof, the LED package including: a lead frame receiving power supplied thereto; an LED chip electrically connected to the lead frame; a heat slug provided with a mounting part having the LED chip mounted thereon and outwardly discharging heat generated by the LED chip; and a body part covering at least a portion of an outer circumferential surface of the heat slug, wherein at least a portion of a circumferential region of the body part has higher heat resistance than that of an internal region thereof.

### TECHNICAL FIELD

The present invention relates to a light emitting diode (LED) package and a manufacturing method thereof, and more particularly, to an LED package including a heat slug to have excellent heat dissipation efficiency and a manufacturing method thereof.

### BACKGROUND ART

In general, light emitting diodes (LEDs), diodes emitting energy generated during the recombination of electrons and holes as light, may include red LEDs using GaAsP, green LEDs using GaP, and the like. In addition, as nitride semiconductors using nitrides, including GaN, have recently received considerable attention as photoelectric materials and core materials of electronic devices due to excellent physical and chemical characteristics thereof, nitride semiconductor LEDs have also been prominent. Nitride semiconductor LEDs may generate light within the ultraviolet region as well as green and blue regions and may be applied to the field of devices such as full color electronic displays, lighting devices and the like, in accordance with a significant improvement in luminance thereof due to the development of the technology thereof.

The LEDs may be manufactured in various forms of packages having LEDs mounted therein to be used according to a field of application.

Meanwhile, LEDs may need an increased amount of power in order to be applied to devices requiring high degrees of luminance, such as lighting devices and the like, such that a great quantity of heat may be generated from the LEDs. In a case in which the heat is not effectively dissipated, characteristics of the LEDs may be changed or the lifespan thereof may be shortened.

In order to solve the defects, an LED package having a heat slug in order to efficiently dissipate heat generated by an LED to the outside thereof has been proposed.

FIG. 1 illustrates an LED package having a heat slug according to the related art, disclosed in PCT publication WO2002/084749 (Title: CONDUCTOR FRAME AND HOUSING FOR A RADIATION-EMITTING COMPONENT, RADIATION EMITTING COMPONENT AND METHOD FOR PRODUCING THE SAME).

Referring to FIG. 1, an LED package 10 according to the related art may include a heat slug 4 outwardly discharging heat generated by an LED chip 5, a lead frame 2 including a connection portion 2a electrically connected to the LED chip 5 via a wire 6, and a body part 1 having the lead frame 2 and the heat slug 4 insert-molded therein. A mounting part 3 may be formed on an upper surface of the heat slug 4, the mounting part 3 having the LED chip 5 mounted thereon. A reflective part 8 may be formed in the center of the body part 1 in order to increase extraction efficiency of light radiated from the LED chip 5.

However, in the LED package 10 according to the related art, since the body part 1 is formed of a single material, a portion of the package adjacent to the mounting part 3 in which the LED chip 5 is mounted and a sufficient amount of light reflection needs to be generated, and an edge portion of the package requiring excellent thermal characteristics due to external environmental factors such as solar light radiation according to an installation position or a structure of the LED package, engine heat emission, heat generated by another LED package adjacent to the corresponding LED package, and the like, may be formed of the same material as each other.

Thus, in order to secure performances of both the portion adjacent to the mounting part 3 and the edge portion corresponding to a surface of the package, the body part 1 may need to be formed of a material having excellent light reflectance as well as excellent thermal stability. However, the securing of a material having excellent light reflectance as well as excellent thermal stability may be difficult and further, costs required for obtaining the material may be relatively high. Meanwhile, a method of coating or attaching a high light reflective material to a region of the reflective part 8 may be used in order to increase light reflection efficiency of the reflective part 8, but in this case, a separate process may be required, resulting in a complicated manufacturing process.

In addition, in the LED package 10 according to the related art, light radiated from the LED chip 5 may be reflected by the reflective part 8, thereby leading to a degradation in extraction efficiency of light radiated from the LED chip 5 in a horizontal direction or in close proximity to the horizontal direction.

Further, in the LED package 10 according to the related art, since the body part 1 may be formed by insert-molding the heat slug 4 simultaneously with the lead frame 2, processing difficulties such as the fixation of the heat slug 4 simultaneously with the lead frame 2, during an insert-molding process may exist.

### DISCLOSURE

### Technical Problem

The present disclosure is provided to solve at least a part of the defects described above, and an aspect of the present disclosure provides a light emitting diode (LED) package having high extraction efficiency of light radiated from an LED chip and excellent thermal stability in an edge portion thereof, and a manufacturing method thereof.

An aspect of the present disclosure also provides an LED package enabling a lead frame and a heat slug to be easily fixed to each other by forming a plurality of body parts, and a manufacturing method thereof.

An aspect of the present disclosure also provides an LED package allowing for easy and stable electrical connection process between an LED chip and a lead frame by disposing terminals of the LED chip and terminals of the lead frame to be adjacent to each other, and a manufacturing method thereof.

An aspect of the present disclosure also provides an LED package having significantly high extraction efficiency of light radiated from the LED chip and a manufacturing method thereof.

### Technical Solution

According to an aspect of the present disclosure, there is provided an LED package including: a lead frame receiving power supplied thereto; an LED chip electrically connected to the lead frame; a heat slug provided with a mounting part having the LED chip mounted thereon and outwardly discharging heat generated by the LED chip; and a body part covering at least a portion of an outer circumferential surface of the heat slug, wherein at least a portion of a circumferential region of the body part has higher heat resistance than that of an internal region thereof.

According to another aspect of the present disclosure, there is provided an LED package including: a lead frame receiving power supplied thereto; an LED chip electrically connected to the lead frame; a heat slug provided with a mounting part having the LED chip mounted thereon and outwardly discharging heat generated by the LED chip; and a body part covering at least a portion of an outer circumferential surface of the heat slug, wherein a central portion of an upper surface portion of the body part has higher reflectivity than that of at least a portion of the remaining portion of the body part.

The body part may include a first body receiving the lead frame and covering at least a portion of the outer circumferential surface of the heat slug and a second body formed to surround at least a portion of an outer surface of the first body.

A central portion of an upper surface portion of the body part may have higher reflectivity than that of at least a portion of the remaining portion of the body part.

The second body may be formed of a material having soldering resistance higher than that of the first body.

The first body and the second body may be formed of a material including a liquid crystal polymer (LCP). The first body may include titanium dioxide (TiO₂) or silicate based powder components.

The at least a portion of the circumferential region of the body part may include a powder component including carbon black. An amount of the carbon black included in the at least a portion of the circumferential region of the body part may be higher than that in the internal region of the body part.

The first body may receive a portion of the lead frame therein such that terminals of the lead frame are exposed upwardly.

The first body may include an opening formed in a center thereof, the opening receiving an upper part of the heat slug therein, and the second body may be formed to surround outer circumferential surfaces of the first body and a lower part of the heat slug and may fix the first body and the heat slug thereto.

The mounting part of the heat slug may be positioned to protrude upwardly from the upper surface portion of the first body, such that light radiated from the LED chip in a horizontal direction is not blocked.

The terminals of the lead frame may be disposed to be adjacent to terminals of the LED chip.

The terminals of the LED chip are disposed at vertices of the LED chip, and the terminals of the lead frame may be extended from the terminals of the LED chip in a diagonal direction or positioned within an angle range of 20° from the diagonal direction.

The LED package may further include: a lens part installed over the LED chip and allowing light radiated from the LED chip to be transmitted therethrough.

The mounting part of the heat slug, having the LED chip mounted thereon, may be provided at the highest position of the heat slug.

The lead frame may include a joining part supporting a connecting part that supplies power to the terminals of the lead frame when the body part is formed.

At least a portion of a side surface of the lower part of the heat slug may be exposed from the body part.

According to another aspect of the present invention, there is provided a manufacturing method of an LED package, including: forming a body part such that the body part receives a portion of a lead frame and a portion of a heat slug therein, while at least a portion of a circumferential region of the body part has higher heat resistance than that of the internal region; and mounting an LED chip on a mounting part provided on an upper surface of the heat slug and electrically connecting the LED chip to terminals of the lead frame.

The forming of the body part may include: forming a first body having an opening in a center thereof by molding the lead frame therein in such a manner that a portion of the lead frame is received in the first body, while terminals of the lead frame are upwardly exposed, and molding a second body fixing outer circumferential surfaces of the first body and the heat slug thereto while the heat slug is fitted into the opening of the first body.

The first body may be formed of a material having reflectivity higher than that of the second body.

The second body may be formed of a material having heat resistance higher than that of the first body.

The first body and the second body may be formed of a material including a liquid crystal polymer (LCP).

The first body may include titanium dioxide (TiO₂) or silicate based powder components, and the second body may include a powder component including carbon black.

### Advantageous Effects

According to an embodiment of the present disclosure as described above, at least a portion of a circumferential region of a body part may have a higher degree of heat resistance than that of an internal region thereof, thermal stability may be excellent in the circumferential region of the body part. In addition, according to an embodiment of the present disclosure, a central portion of an upper surface portion of the body part, adjacent to an LED chip, may have a higher degree of reflectivity than that of at least one portion of the remaining portion of the body part, such that light extraction efficiency may be improved.

In addition, according to an embodiment of the present disclosure, a first body adjacent to the LED chip may be formed of a material having a high degree of reflectivity, such that extraction efficiency of light radiated from the LED chip may be increased. Further, according to an embodiment of the present disclosure, a second body corresponding to a surface of the LED package may be formed of a material having high heat resistance or soldering resistance to obtain excellent thermal stability.

Moreover, according to an embodiment of the present disclosure, the second body fixing the first body and a heat slug thereto may be molded while the heat slug is fitted in the first body after only a lead frame is insert-molded in the first body, whereby the lead frame and the heat slug may be stably and easily fixed to each other.

Moreover, according to an embodiment of the present disclosure, since positions of terminals (electrodes) of the LED chip and terminals of the lead frame are set to be adjacent to each other, process properties of a wire connection process for connecting the terminals of the LED chip and the terminals of the lead frame may be improved to significantly reduce connection defects. In particular, in a case in which the terminals (electrodes) of the LED chip and the terminals of the lead frame are positioned with a minimum distance therebetween, a wire connection distance may be minimized, such that process properties of the wire connection process may be significantly increased and connection defects may be significantly reduced.

Moreover, according to an embodiment of the present disclosure, the upper surface portion of the body part may be formed in a position lower than the mounting part of the heat slug, that is, the LED chip, such that light radiated from the LED chip in a horizontal direction may not be blocked by the body part. Thus, light emissions may be performed at a wide angle and light extraction efficiency may be enhanced.

Moreover, according to an embodiment of the present disclosure, the mounting part of the heat slug having the LED chip mounted thereon may be provided on the heat slug at the highest position thereof, such that light radiated from the LED chip in a horizontal direction may not be blocked by the heat slug. Thus, light emissions may be performed at a wide angle and light extraction efficiency may be enhanced.

Moreover, according to an embodiment of the present disclosure, heat emission efficiency of the heat slug may be improved by exposing at least a portion of a side surface of the lower part, as well as the lower part of the heat slug from the body part.

Moreover, according to an embodiment of the present disclosure, when the lead frame includes a joining part so as to support a connecting part supplying power to the terminals of the lead frame, such that the positions of the terminals of the lead frame and the connection part may be stably maintained during the formation of the body part to significantly reduce process defects and improve working efficiency.

### DESCRIPTION OF DRAWINGS

FIG. 1 is a perspective view of an LED package according to the related art.

FIG. 2 is a partially cut-away perspective view of an LED package according to an embodiment of the present disclosure.

FIG. 3 is a perspective view illustrating an example of an initial state of a lead frame shown in FIG. 2.

FIG. 4 is a perspective view illustrating an example of a heat slug shown in FIG. 2.

FIGS. 5 through 9 are explanation views illustrating a manufacturing method of an LED package according to an embodiment of the present disclosure, in sequence.

Here, FIG. 5 is a perspective view illustrating a state in which a first body is formed on the lead frame,

FIG. 6 is a perspective view illustrating a state in which the heat slug is mounted in an opening of the first body,

FIG. 7 is a perspective view illustrating a state in which a second body is molded in the first body,

FIG. 8 is a plan view of FIG. 7, and

FIG. 9 is a perspective view illustrating a state in which an LED chip is mounted.

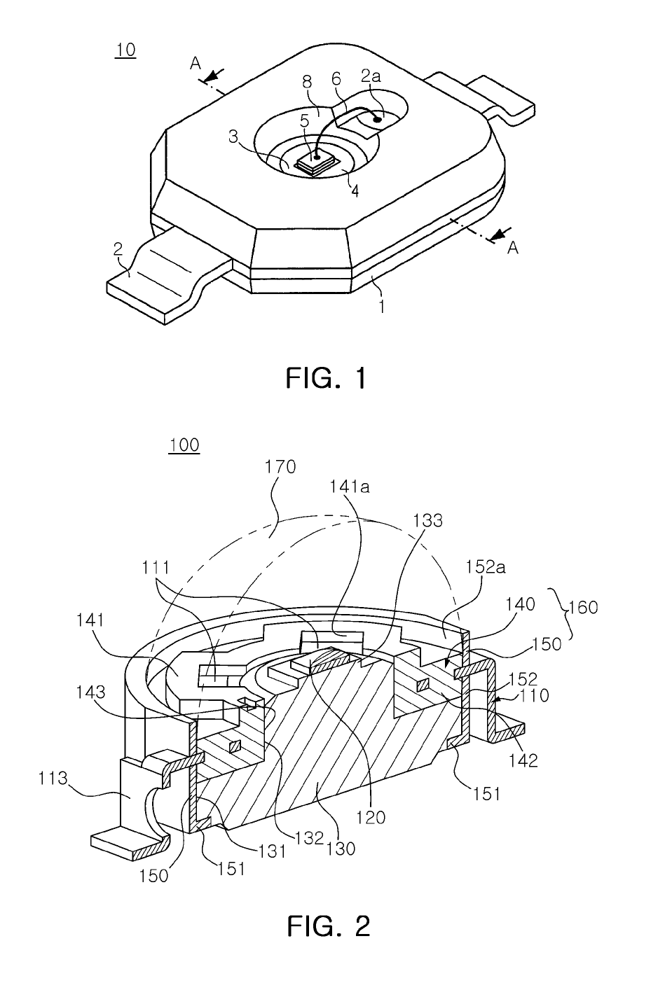

### BEST MODE

Hereinafter, exemplary embodiments of the present disclosure will be described in detail with reference to the accompanying drawings.

First, an LED package 100 according to an embodiment of the present disclosure will be described with reference to FIGS. 2 through 4 and FIG. 9.

As illustrated in FIG. 2, the LED package 100 according to the embodiment of the present disclosure may be configured to include a lead frame 110 receiving power supplied thereto, an LED chip 120 electrically connected to the lead frame 110, a heat slug 130 provided with a mounting part 133 having the LED chip 120 mounted thereon and outwardly discharging heat generated by the LED chip 120, and a body part 160 formed to receive the heat slug 130 and the lead frame 110 therein, and may further include a lens part 170 installed over the LED chip 120.

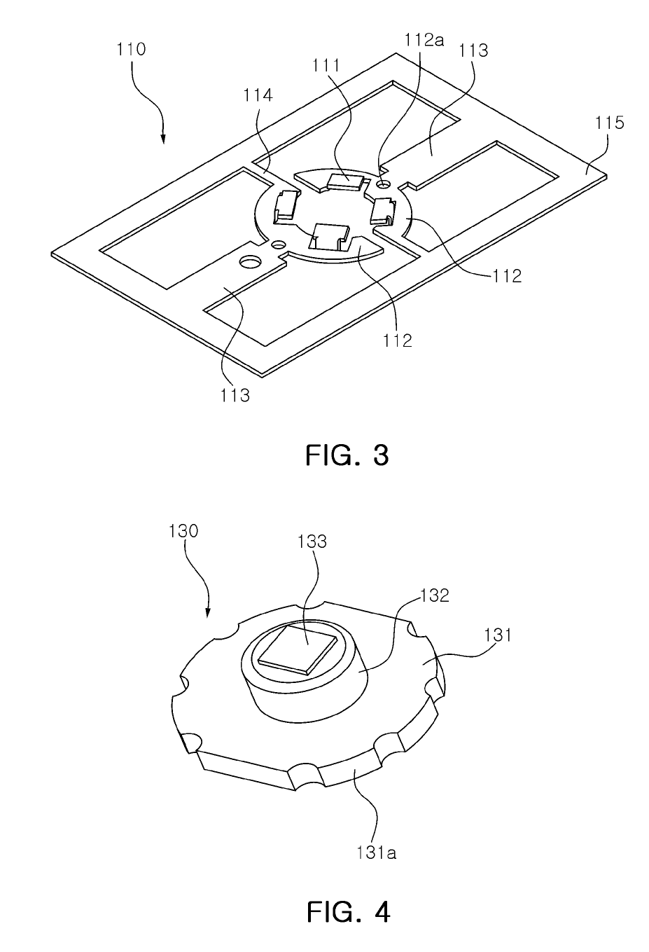

As illustrated in FIG. 3, the lead frame 110 may include one or more terminals 111 disposed in the center thereof and electrically connected to the LED chip 120 via a wire (See 125 of FIG. 9), a connecting part 113 connected to a power supply unit (not shown) so as to supply power to the terminals 111, and a coupling part 112 coupling the terminals 111 to the connecting part 113. In addition, the lead frame 110 may have an outer frame part 115 formed in an edge thereof in order to facilitate workability and/or to prevent deformation of the lead frame 110 during the molding thereof with the body part 160 to be described later, and a joining part 114 joining the outer frame part 115 and the coupling part 112. The joining part 114 may support the connecting part 113 such that a predetermined position of the connecting part 113 may be stably maintained during a molding process. The outer frame part 115 or the joining part 114 may be temporally used during the manufacturing of the LED package 100, and may be configured such that at least a portion thereof is severed at the time of the completion of the LED package 100.

In addition, in a case in which the lead frame 110 includes a plurality of the terminals 111, a single connecting part 113 may be connected to the plurality of terminals 111, whereby the number of connecting parts 113 provided between the power supply unit (not shown) and the terminals 111 may be significantly reduced. By way of example, referring to FIG. 3, when the lead frame 110 includes two connecting parts 113 and four terminals 111, each of the connecting parts 113 may be connected to two terminals 111 through the coupling part 112. In this case, the two terminals 111 connected to each connecting part 113 may be arranged diagonally with respect to the connecting part 113 and have an angle of approximately 45 degrees with respect thereto.

Meanwhile, although FIG. 3 illustrates the lead frame 110 having four terminals 111, but is merely provided by way of example. The terminals 111 of the lead frame 110 may be variously changed depending on the number of terminals (electrodes) of the LED chip 120, requiring wire connections.

Further, as illustrated in FIG. 4, the heat slug 130 may be formed of a material having high thermal conductivity, for example, a metal material, in order to outwardly discharge heat generated by the LED chip 120 mounted on the mounting part 133 provided on an upper portion of the heat slug 130. The mounting part 133 may be formed on the upper portion of the heat slug 130 and may be configured such that light emission efficiency of the LED chip 120 may be maintained, without light radiated from the LED chip 120 being blocked. By way of example, the mounting part 133 may be provided at the highest position of the heat slug 130, such that light radiated from the LED chip 120 in a horizontal direction or in close proximity to the horizontal direction may not be blocked.

Meanwhile, heat generated by the LED chip 120 may pass through an upper part 132 of the heat slug 130 via the mounting part 133 of the heat slug 130 and may be outwardly discharged through a lower surface of a lower part 131. In this case, the heat slug 130 may be configured in such a manner that the lower surface of the lower part 131 is exposed to the outside of the body part 160 and thus, heat generated by the LED chip 120 may be efficiently, outwardly discharged to the outside. Here, heat emission efficiency of the heat slug 130 may be further improved by exposing a portion 131a of a side surface of the lower part 131 as well as the lower surface of the lower part 131 of the heat slug 130, from the body part 160. In addition, the lower part 131 of the heat slug 130 may have a cross-sectional area greater than that of the upper part 132 of the heat slug 130, whereby heat generated by the LED chip 120 may be promptly, outwardly discharged through a wide area of the lower part 131.

Meanwhile, referring to FIG. 2, the body part 160 may be divided into a circumferential region corresponding to an edge thereof and an internal region positioned within the circumferential region. By way of example, the circumferential region may be configured of a side surface portion 152 and an upper surface portion 141 of the body part 160, and the internal region may be a region surrounded by the circumferential region.

In this case, at least a portion of the circumferential region of the body part 160 may be configured to have a higher degree of heat resistance than that of the internal region, and maintain thermal stability with respect to external environmental factors. In detail, thermal stability may be required depending on an installation place or a structure of the LED package 100, and for example, the LED package 100 may have thermal stability with respect to various factors, for example, heating due solar light radiation in the case of being used in the outdoors such as in street lamps, heating due to another LED package adjacent to the corresponding LED package in the case of being used in an LED module, heating from an engine in the case of being used in a vehicle headlamp, and the like. In order to ensure such thermal stability, the side surface portion 152 corresponding to the circumferential region of the body part 160, at least, may be formed of a material having a level of heat resistance higher than that of the internal region. Meanwhile, FIG. 2 illustrates a case in which the lower surface of the lower part 131 of the heat slug 130 is exposed from the body part 160, and the circumferential region of the body part 160 does not include the lower surface of the lower part. However, in a case in which the circumferential region of the body part 160 includes the lower surface of the lower part, the lower surface of the body part 160 may be formed of a material having heat resistance higher than that of the internal region.

In addition, a central portion of the upper surface portion 141 of the body part 160, adjacent to the mounting part 131 on which the LED chip 120 is mounted, may be configured to have a higher degree of reflectivity than that of at least a portion of the remaining portion of the body part 160, such that light extraction efficiency of the LED package 100 may be improved. That is, such a portion formed of a high reflective material may be the entirety of the upper surface portion 141 of the body part 160. However, as illustrated in FIG. 2, in a case in which the side surface portion 152 of the circumferential region includes a protrusion 152a protruded upwardly, the portion formed of a high reflective material may configure the upper surface portion 141 of the body part 160, except for the protrusion 152a.

Unlike as described above, the body part 160 may be divided into a plurality of bodies including a first body 140 covering at least a portion of an outer circumferential surface of the heat slug 130 and a second body 150 formed to surround an outer circumferential surface of the first body 140.

That is, the first body 140 may include a lead frame receiving portion 142 receiving a portion of the lead frame 110 therein, and an opening 143 formed in the center of the lead frame receiving portion 142 and covering an outer circumferential surface of the upper part 132 of the heat slug 130. In this case, the lead frame receiving portion 142 may be insert-molded while having the lead frame 110 received therein, and the terminals 111 of the lead frame 110 may be upwardly exposed through exposure grooves 141a and electrically connected to the LED chip 120. Meanwhile, since a molding material forming the first body 140 may be received in through holes (112a of FIG. 3) formed in the lead frame 110 inserted into the lead frame receiving portion 142, connection strength between the lead frame 110 and the first body 140 may be improved.

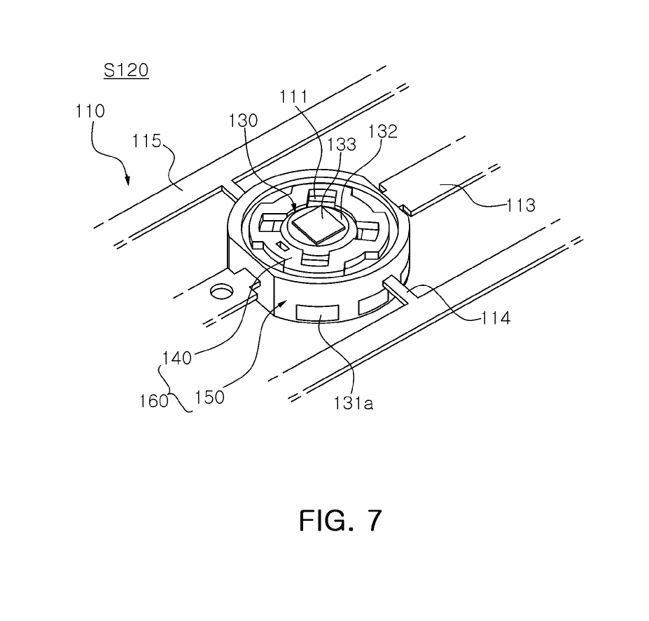

Further, the second body 150 may be molded to surround the outer circumferential surfaces of the first body 140 and the heat slug 130 to allow the first body 140 and the heat slug 130 to be fixed thereto. To this end, the second body 150 may be molded and formed so as to surround an outer circumferential surface of the lower part 131 of the heat slug 130, the upper part 132 of which is received in the opening 143 of the first body 140, and the outer circumferential surface of the first body 140. In this case, the second body 150 may include an end jaw portion 151 extended inwardly from the side surface portion 152 in order to prevent the heat slug 130 from downwardly falling. In addition, as illustrated in FIGS. 7 and 9, the second body 150 may be formed such that the portion 131a of the lower part 131 of the heat slug 130 is exposed from the second body 150 in order to improve heat dissipation performance.

Meanwhile, since the first body 140 may be disposed to be adjacent to the heat slug 130 on which the LED chip 120 is mounted, the first body 140 may be formed of a material having a higher degree of reflectivity than that of the second body 150 forming an outer portion of the body part 160 in order to increase light extraction efficiency of the LED package 100. In this case, the first body 140 may be formed of a material having high reflectivity at a wavelength of 380 to 780 nm in the visible light region or at a wavelength of 300 to 800 nm in a region adjacent to the visible light region. By way of example, 70% or more of reflectivity may be set, but the present disclosure is not limited thereto. The first body 140 may be formed of a material having the higher reflectivity in order to increase light extraction efficiency.

In addition, since the second body 150 may form a circumference of the body part 160, it may need to have thermal stability with respect to external environmental factors, for example, various factors including heating due solar light radiation according to an installation place or a structure of the LED package, heating due to another LED package adjacent to the corresponding LED package, heating from an engine, and the like. In order to ensure such thermal stability, the second body 150 may be formed of a material having a higher degree of heat resistance than that of the first body 140. In an aspect of heat resistance, the second body 150 may be formed of a material having soldering resistance higher than that of the first body 140. Soldering resistance may refer to a temperature at which blisters or deformations are started to be generated at the time of inserting a material into high temperature lead, and in the case of high soldering resistance, a sufficient amount of resistance may be generated against external environmental factors.

As described above, the first body 140 and the second body 150 may be formed of different materials in accordance with positional features thereof, such that characteristics required for the LED package 100 may be maximally exhibited.

By way of example, the first body 140 and the second body 150 may be formed of a material including a liquid crystal polymer (LCP) having excellent moldability due to having excellent heat resistance and electrical insulation, while having a low melting point.

In this case, the first body 140 and the second body 150 may include different components in order to secure reflectivity and thermal stability. For example, an LCP including titanium dioxide (TiO₂) or silicate based powder components to implement white or a brilliant color as compared to that of the second body 150 may be used for the first body 140, and an LCP including powder components such as carbon black to implement black or a dark color as compared to that of the first body 140 may be used for the second body 150.

Meanwhile, in a case in which the body part 160 is divided into the circumferential region and the internal region, at least a portion of the circumferential region of the body part 160 may be formed of an LCP including a powder component including carbon black. By way of example, at least the side surface portion 152 of the circumferential region may be formed of an LCP including a powder component including carbon black to realize thermal stability. In addition, the amounts of carbon black contained in at least a portion of the circumferential region of the body part 160 (for example, the side surface portion 152) may be configured to be higher than that in the internal region (for example, the central portion), performance in the circumferential region of the body part 160, requiring thermal stability or heat resistance, may be sufficiently implemented.

Meanwhile, as materials of the first body 140 and the second body 150, other engineering plastics such as polyphenylene sulfide and the like, as well as the LCPs, may be used. As the powder components (or inorganic substances) contained therein, various inorganic substances having specific colors such as silicon oxide (SiO₂), aluminum oxide (Al₂O₂), barium sulfate (BaSO₄), boric oxide (B₂O₃) and the like or mixtures thereof may be used.

In addition, the upper surface portion 141 of the first body 140 may be formed in a position lower than the mounting part 133 of the heat slug 130, and may be configured such that light radiated from the LED chip 120 in close proximity to a horizontal direction may not be blocked by the body part 160, in other words, light emissions may be performed at a wide angle and light extraction efficiency may be high. More preferably, a top portion of the side surface portion 152 of the second body 150 may be formed in a position lower than the mounting part 133 of the heat slug 130, and may be configured such that light radiated from the LED chip 120 in close proximity to a horizontal direction may not be blocked by the body part 160.

In addition, the lens part 170 through which light radiated from the LED chip 120 transmits may be installed over the LED chip 120, and a shape thereof is not limited to a hemispherical shape such as that illustrated in FIG. 2 and may be various according to an intended use of the LED package 100. In addition, the side surface portion 152 of the second body 150 may include the protrusion 152a protruded upwardly, and the lens part 170 may be stably mounted on the protrusion 152a.

Meanwhile, as illustrated in FIG. 9, positions of the terminals 111 of the lead frame 110 may be set to be adjacent to terminals (electrodes) of the LED chip 120. By way of example, as illustrated in FIG. 9, in a case in which the terminals of the LED chip 120 are positioned to be adjacent to vertices of the LED chip 120, the terminals 111 of the lead frame 110 may be positioned to be adjacent to the vertices of the LED chip 120. In this case, the terminals 111 of the lead frame 110 may be installed to be diagonally extended from the terminals of the LED chip 120 such that the respective terminals of the LED chip 120 and the respective terminals 111 of the lead frame 110 are connected to one another with a minimum distance therebetween. However, in consideration of work tolerance during a wire connection process, the terminals 111 of the lead frame 110 may be positioned to be diagonal with respect to the terminals of the LED chip 120 within a predetermined angle range (for example, at an angle of) ±20°. However, the positions of the terminals 111 of the lead frame 110 may be changed according to the positions of the terminals of the LED chip 120, and by way of example, in a case in which terminals (electrodes) of the LED chip 120 are positioned in the center of corners thereof, the terminals 111 of the lead frame 110 may be configured to be positioned on lines connecting the center of the LED chip 120 and the terminals or within a predetermined angle range from the lines.

In this manner, the terminal (electrode) of the LED chip 120 and the terminal 111 of the lead frame 110 are positioned to be adjacent to each other, process properties of a connection process of the wire 125 may be improved to significantly reduce connection defects.

Meanwhile, FIG. 9 illustrates a case in which four terminals (electrodes) are formed on the LED chip 120 and four terminals 111 are formed on the lead frame 110, but is merely provided by way of example. The number of the terminals of the LED chip 120 may be variously changed according to a structure of the LED chip 120 or the required characteristics thereof. For example, in a case in which a lower surface of the LED chip 120 is used as an electrode (for example, “a negative electrode”), a single “positive” electrode may be formed on an upper surface of the LED chip 120, such that a single wire may be used. In a case in which a negative electrode and a positive electrode are formed on the upper surface of the LED chip 120, two wires may also be used. In addition, in the case of a high power LED chip, a plurality of wires for the positive electrode may be configured in consideration of an amount of current in the positive electrode. As described above, even in a case in which the number or positions of the terminals (electrodes) of the LED chip 120 are changed, the terminals 111 of the lead frame 110 may be configured to be positioned on lines connecting the center of the LED chip 120 and the respective terminals thereof or within a predetermined angle range from the lines.

In order to connect the respective terminals of the LED chip 120 and the respective terminals 111 of the lead frame 110 to one another with a minimum distance therebetween, the terminals 111 of the lead frame 110 may be configured to be positioned on lines connecting the center of the LED chip 120 and the respective terminals or within a predetermined angle range from the lines.

The LED package 100 according to an embodiment of the present invention as described above may be configured as a single LED module by using a plurality of LED chips 120 each having the heat slug 130. Such an LED module may be implemented as an LED module system having a power supply device and an external structure.

The LED module system may be used in room lighting devices, street lamps, LED signboards, vehicle headlamps and various types of lighting devices.

By way of example, in a case in which an LED module system is used as a street lamp, a single LED module or a plurality of LED modules including a plurality of LED chips 120 each having the heat slug 130 may be installed, a power supply device for driving the LED module may be provided. Such a power supply device may include a rectifying unit rectifying alternating current (AC) voltage input thereto and generating input direct current (DC) voltage, a power factor correcting unit correcting a power factor of the input DC voltage, and the like, thereby driving the LED module.

As described above, since the LED package 100 according to the embodiment of the present disclosure may have excellent heat dissipation performance due to the heat slug 130 and thermal stability with respect to external environmental factors, it may be efficiently used in various intended uses.

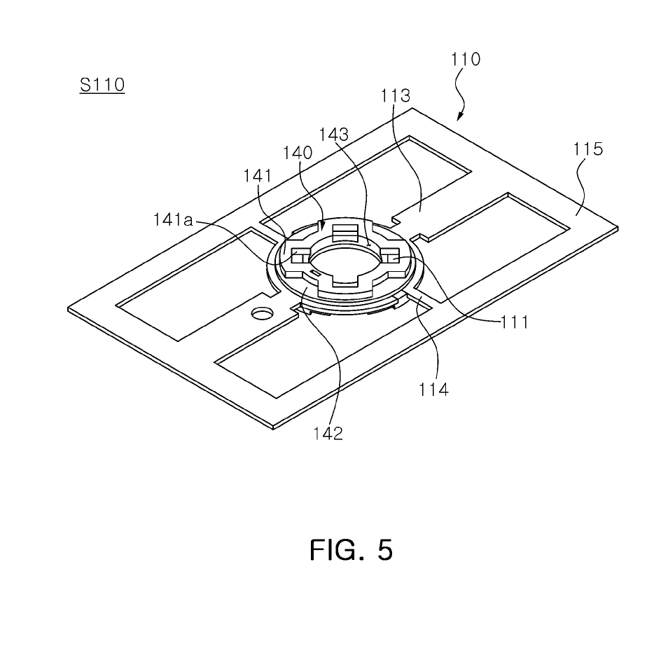

Next, a manufacturing method of the LED package 100 according to another embodiment of the present disclosure will be described with reference to FIGS. 5 to 9. The manufacturing method of the LED package 100 according to another embodiment of the present disclosure may be configured to include a process of forming the body part 160 (S110 and S120) such that the body part 160 receives a portion of the lead frame 110 and a portion of the heat slug 130 therein, while at least a portion of the circumferential region of the body part 160 has a higher degree of heat resistance than that of the internal region, and a process of mounting the LED chip 120 on the mounting part 133 provided on the upper surface of the heat slug 130 and electrically connecting the LED chip 120 to the terminals 111 of the lead frame 110 (S130).

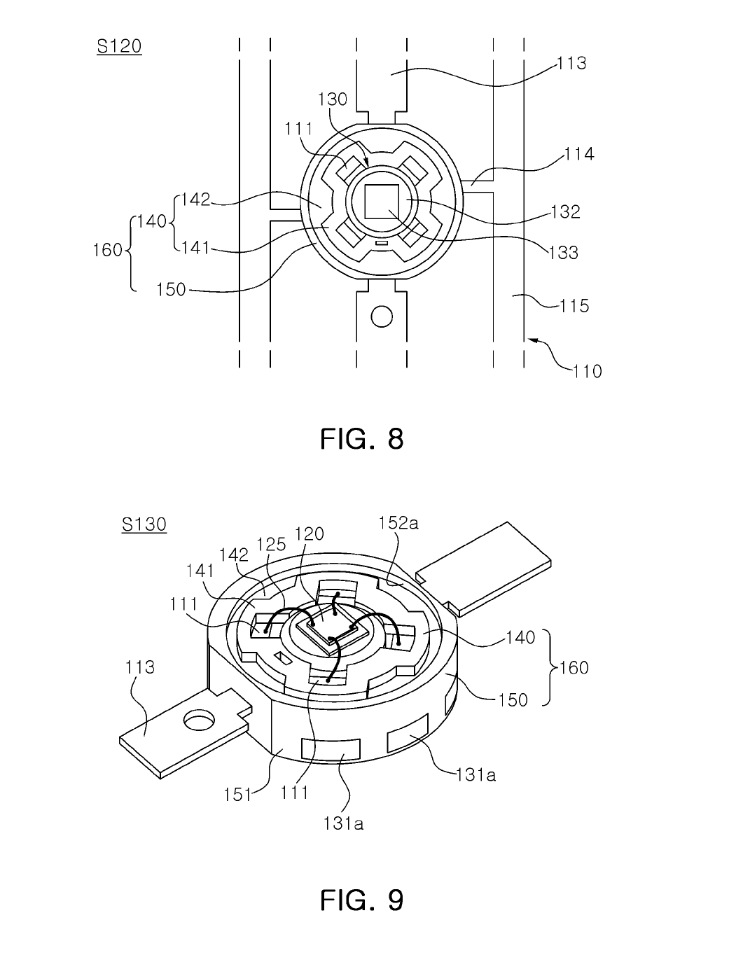

In this case, the process of forming the body part 160 (S110 and S120) may be configured to include a process of forming the first body 140 (S110 of FIG. 5) by insert-molding the lead frame 110 and a process of molding the second body 150 (S120 of FIGS. 7 and 8) fixing the outer circumferential surfaces of the first body 140 and the heat slug 130 thereto.

Hereinafter, respective processes will be described in detail.

First, as illustrated in FIG. 3, the lead frame 110 including the terminals 111 electrically connected to the LED chip 120 and the connecting parts 113 connecting the terminals 111 to an external power supply may be prepared. However, the lead frame 110 used in the manufacturing of the LED package 100 according to the embodiment of the present disclosure is not limited to having a shape such as that illustrated in FIG. 3, and in the lead frame 110, the number of the terminals 111, a structure of the connection parts 113 connecting the terminals 111 to an external power supply, a structure of the outer frame part 115 connected to the connection parts 113, and the like may be changed.

Next, in the process of forming the first body (S110), the first body 140 may be formed by insert-molding the lead frame 110 therein in such a manner that a portion of the center of the lead frame 110 is received in the first body 140, while the terminals 111 of the lead frame 110 are upwardly exposed, as illustrated in FIG. 5.

By way of example, the first body 140 may include the lead frame receiving portion 142 receiving the coupling part (112 of FIG. 3) of the lead frame 110 therein, and the opening 143 formed in the center of the lead frame receiving portion 142 and covering the outer circumferential surface of the upper part 132 of the heat slug 130. In this case, the terminals 111 of the lead frame 110 may be upwardly exposed through the exposure grooves 141a and electrically connected to the LED chip 120.

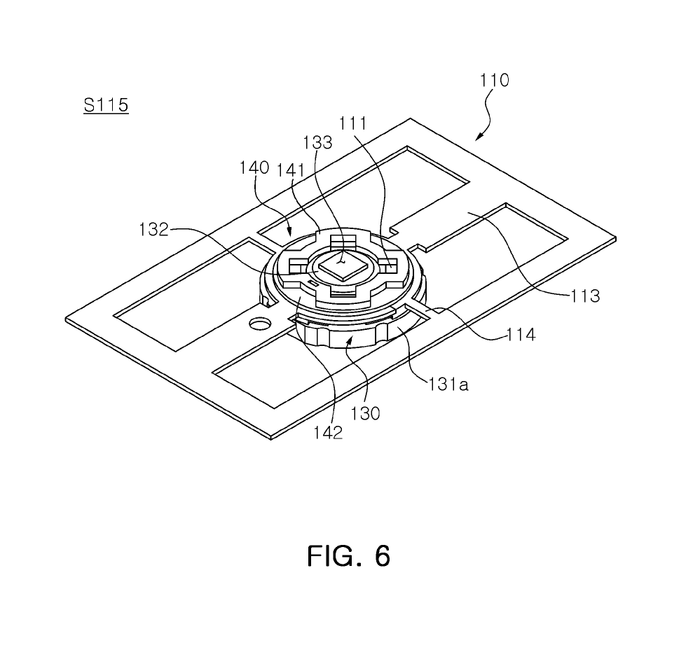

Next, the upper part 132 of the heat slug 130 may be fitted in the opening 143 of the first body 140, insert-molded with the lead frame 110 as described above (S115 of FIG. 6), and in this state, the second body 150 may be formed (S120 of FIGS. 7 and 8).

By way of example, the second body 150 may be formed to surround the outer circumferential surfaces of the first body 140 and the heat slug 130 to fix the first body 140 and the heat slug 130 thereto. To this end, the second body 150 may be molded and formed so as to surround the outer circumferential surface of the lower part 131 of the heat slug 130, the upper part 132 of which is received in the opening 143 of the first body 140, and the outer circumferential surface of the first body 140. (See FIG. 2).

As described above, when the formation of the first body 140 and the second body 150 that fix the lead frame 110 and the heat slug 130 thereto is finished, the LED chip 120 may be mounted on the mounting part 133 provided on the upper surface of the heat slug 130, and the LED chip 120 and the terminals 111 of the lead frame 110 may be electrically connected to each other via the wire 125 or the like (S130 of FIG. 9). Moreover, necessary portions of the LED package 100 such as the outer frame part 115 and the joining part 114 may be severed from the lead frame 100.

Thereafter, as illustrated in FIG. 2, the lens part 170 may be mounted on an upper end portion of the body part 160 so as to form a path of light radiated from the LED chip 120.

Meanwhile, since the first body 140 may be disposed to be adjacent to the heat slug 130 having the LED chip 120 mounted thereon, the first body 140 may be formed of a material having a higher degree of reflectivity than that of the second body 150 forming the outer portion of the body part 160 in order to increase light extraction efficiency of the LED package 100.

In addition, since the second body 150 may form the circumference of the body part 160, it may need to have thermal stability with respect to various factors including heating due solar light radiation, heating due to another LED package adjacent to the corresponding LED package, heating from an engine, and the like. For the thermal stability, the second body 150 may be formed of a material having a higher degree of heat resistance than that of the first body 140. In an aspect of heat resistance, the second body 150 may be formed of a material having soldering resistance higher than that of the first body 140.

As described above, the first body 140 and the second body 150 may be formed of different materials in accordance with positional features thereof, such that characteristics required for the LED package 100 may be maximally realized.

By way of example, the first body 140 and the second body 150 may be formed of a material including a liquid crystal polymer (LCP) having excellent moldability due to having excellent heat resistance and electrical insulation, while having a low melting point.

In this case, the first body 140 and the second body 150 may include different components in order to secure reflectivity and thermal stability. For example, an LCP including titanium dioxide (TiO₂) or silicate based powder components to implement white or a brilliant color as compared to that of the second body 150 may be used for the first body 140, and an LCP including a powder component including carbon black to implement black or a dark color as compared to that of the first body 140 may be used for the second body 150.

However, as materials of the first body 140 and the second body 150, other engineering plastics such as polyphenylene sulfide and the like, as well as the LCPs, may be used. As the powder components (or inorganic substances) contained therein, various inorganic substances or mixtures thereof may be used.

While the present disclosure has been shown and described in connection with the embodiments, it will be apparent to those skilled in the art that modifications and variations can be made without departing from the spirit and scope of the disclosure as defined by the appended claims.

1-24. (canceled)

25. An LED package comprising:
a lead frame receiving power supplied thereto;
an LED chip electrically connected to the lead frame;
a heat slug provided with a mounting part having the LED chip mounted thereon and outwardly discharging heat generated by the LED chip; and
a body part covering at least a portion of an outer circumferential surface of the heat slug,
wherein at least a portion of a circumferential region of the body part has higher heat resistance than that of an internal region thereof.

26. The LED package of claim 25, wherein the body part includes a first body receiving the lead frame and covering at least a portion of the outer circumferential surface of the heat slug and a second body formed to surround at least a portion of an outer surface of the first body.

27. The LED package of claim 25, wherein a central portion of an upper surface portion of the body part has higher reflectivity than that of at least a portion of the remaining portion of the body part.

28. The LED package of claim 26, wherein the second body is formed of a material having soldering resistance higher than that of the first body.

29. The LED package of claim 26, wherein the first body and the second body are formed of a material including a liquid crystal polymer (LCP).

30. The LED package of claim 29, wherein the first body includes titanium dioxide (TiO₂) or silicate based powder components.

31. The LED package of claim 25, wherein the at least a portion of the circumferential region of the body part includes a powder component including carbon black.

32. The LED package of claim 31, wherein an amount of the carbon black included in the at least a portion of the circumferential region of the body part is higher than that in the internal region of the body part.

33. The LED package of claim 26, wherein the first body receives a portion of the lead frame therein such that terminals of the lead frame are exposed upwardly.

34. The LED package of claim 26, wherein the first body includes an opening formed in a center thereof, the opening receiving an upper part of the heat slug therein, and
the second body is formed to surround outer circumferential surfaces of the first body and a lower part of the heat slug and fixes the first body and the heat slug thereto.

35. The LED package of claim 26, wherein the mounting part of the heat slug is positioned to protrude upwardly from the upper surface portion of the first body, such that light radiated from the LED chip in a horizontal direction is not blocked.

36. The LED package of claim 25, wherein the terminals of the lead frame are disposed to be adjacent to terminals of the LED chip.

37. The LED package of claim 36, wherein the terminals of the LED chip are disposed at vertices of the LED chip, and
the terminals of the lead frame are extended from the terminals of the LED chip in a diagonal direction or positioned within an angle range of 20° from the diagonal direction.

38. The LED package of claim 25 further comprising: a lens part installed over the LED chip and allowing light radiated from the LED chip to be transmitted therethrough.

39. The LED package of claim 25, wherein the mounting part of the heat slug, having the LED chip mounted thereon, is provided at the highest position of the heat slug.

40. The LED package of claim 25, wherein the lead frame includes a joining part supporting a connecting part that supplies power to the terminals of the lead frame when the body part is formed.

41. The LED package of claim 25, wherein at least a portion of a side surface of the lower part of the heat slug is exposed from the body part.

42. A manufacturing method of an LED package, comprising:
forming a body part such that the body part receives a portion of a lead frame and a portion of a heat slug therein, while at least a portion of a circumferential region of the body part has higher heat resistance than that of the internal region; and
mounting an LED chip on a mounting part provided on an upper surface of the heat slug and electrically connecting the LED chip to terminals of the lead frame.

43. The manufacturing method of claim 42, wherein the forming of the body part includes: forming a first body having an opening in a center thereof by molding the lead frame therein in such a manner that a portion of the lead frame is received in the first body, while terminals of the lead frame are upwardly exposed, and
molding a second body fixing outer circumferential surfaces of the first body and the heat slug thereto while the heat slug is fitted into the opening of the first body.

44. The manufacturing method of claim 42, wherein the first body is formed of a material having reflectivity higher than that of the second body.

45. The manufacturing method of claim 44, wherein the second body is formed of a material having heat resistance higher than that of the first body.
